(19) United States
(12) Patent Application Publication
(10) Pub. No.: US 2012/0299034 A1
(43) Pub. Date: Nov. 29, 2012

(54) COLLIMATING LIGHT EMITTING DEVICE AND MANUFACTURING METHOD THEREOF

(76) Inventors: Shiuh CHAO, Hsinchu (TW); Hao-Min Ku, Hsinchu (TW); Chen-Yang Huang, Hsinchu (TW)

(21) Appl. No.: 13/268,277

(22) Filed: Oct. 7, 2011

(30) Foreign Application Priority Data
May 27, 2011 (TW) 100118574

(51) Int. Cl. H01L 33/60

(52) U.S. Cl. 257/91; 438/29; 257/98; 257/E33.06

(57) ABSTRACT

A collimating light emitting device comprises a patterned optical layer able to redirect divergent light to light beam with uniform direction without utilizing external lenses thereby decreasing the size. The collimating light emitting device of the present invention may be utilized as a micro array projection device. The patterned optical layer may also be utilized in a single-die light-emitting device, thereby enhancing collimation. The manufacturing methods of the collimating light emitting device are also presented.

### BACKGROUND OF THE INVENTION

1. Field of the Invention

The present invention relates to a light emitting device and manufacturing method thereof, and more particularly to a light emitting device emitting collimating light and manufacturing method thereof.

2. Description of the Prior Art

In the field of image display, cost reduction, weight reduction and miniaturization are developing trends for both projection devices and display devices. A conventional projection device is consisted of a light source using LED and a plurality of micro-lenses. Although projecting efficiency of the projection device is thus improved, it takes a quite number of lenses to be disposed at the light path of the light emitting diode so as to emit light with good collimation. The conventional projection device is limited by the volume of the lenses itself and the spacing between each lens for miniaturization. Therefore, there have been increasing demands for developing a collimating light emitting device with compact size and good performance.

### SUMMARY OF THE INVENTION

The present invention is directed to a collimating light emitting device and manufacturing method thereof, which comprises a patterned optical layer able to redirect divergent light to a light beam with uniform direction without utilizing external lenses thereby decreasing the size. The collimating light emitting device of the present invention may be utilized as a micro array projection device.

According to an embodiment, a manufacturing method of a collimating light emitting device comprises providing a carrier board; disposing an buffer layer on the carrier board; forming a patterned optical layer on the buffer layer, wherein the patterned optical layer exposes a part of the buffer layer; forming an epitaxial layer to cover exposed the buffer layer and the patterned optical layer by using an procedure of epitaxy of lateral overgrowth (ELOG); forming a first conductivity type layer on the epitaxial layer; forming an active layer on the first conductivity type layer; forming a second conductivity type layer on the active layer; disposing a first electrode layer on the second conductivity type layer and disposing a second electrode layer either below the buffer layer or on the first conductivity type layer, wherein a procedure of removing the carrier board is performed before disposing the second electrode layer below the buffer layer.

According to an embodiment, a collimating light emitting device comprises a buffer layer, a patterned optical layer, an epitaxial layer a first conductivity type layer, an active layer, a second conductivity type layer, a first electrode layer and a second electrode layer. The patterned optical layer is disposed on the buffer layer, wherein the patterned optical layer exposes a part of the buffer layer. The epitaxial layer covers exposed buffer layer and patterned optical layer. The first conductivity type layer is disposed on the epitaxial layer. The active layer is disposed on the first conductivity type layer. The second conductivity type layer is disposed on the active layer. The first electrode layer is disposed on the second conductivity type layer. The second electrode layer is disposed either below the buffer layer or on the first conductivity type layer.

The objective, technologies, features and advantages of the present invention will become more apparent from the following description in conjunction with the accompanying drawings, wherein certain embodiments of the present invention are set forth by way of illustration and examples.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing aspects and many of the accompanying advantages of this invention will become more readily appreciated as the same becomes better understood by reference to the following detailed descriptions, when taken in conjunction with the accompanying drawings, wherein:

FIG. 1 is a manufacturing process flow of a collimating light emitting device according to an embodiment of the present invention;

FIG. 2A to FIG. 2D are schematic cross-sectional views illustrating the manufacturing process flow of the collimating light emitting device according to the embodiment of the present invention;

FIG. 3A and FIG. 3B are respectively schematic cross-sectional view and plan view illustrating the patterned optical layer of the collimating light emitting device according to one embodiment of the present invention;

FIG. 3C and FIG. 3D are respectively schematic cross-sectional view and plan view illustrating the patterned optical layer of the collimating light emitting device according to another embodiment of the present invention;

FIG. 4 is a schematic diagram illustrating the collimating light emitting device according to another embodiment of the present invention;

FIG. 5A is a schematic diagram illustrating the collimating light emitting device according to another embodiment of the present invention, FIG. 5B a schematic diagram rotating the schematic diagram in FIG. 5A for 180 degrees clockwise;

FIG. 6 is a manufacturing process flow of a collimating light emitting device according to another embodiment of the present invention;

FIG. 7A to FIG. 7E are schematic cross-sectional views illustrating the manufacturing process flow of the collimating light emitting device according to the embodiment of the present invention;

FIG. 8A is a schematic diagram illustrating a collimating light emitting device according to another embodiment of the present invention;

FIG. 8B is a schematic diagram illustrating a collimating light emitting device according to another embodiment of the present invention;

FIG. 9 is a manufacturing process flow of a collimating light emitting device according to another embodiment of the present invention;

FIG. 10A to FIG. 10B are schematic cross-sectional views illustrating the manufacturing process flow of the collimating light emitting device according to the embodiment of the present invention;

FIG. 11 is a schematic diagram illustrating a collimating light emitting device according to another embodiment of the present invention; and

FIGS. 12 and 13 are simulation diagrams of light field distribution.

### DESCRIPTION OF THE PREFERRED EMBODIMENT

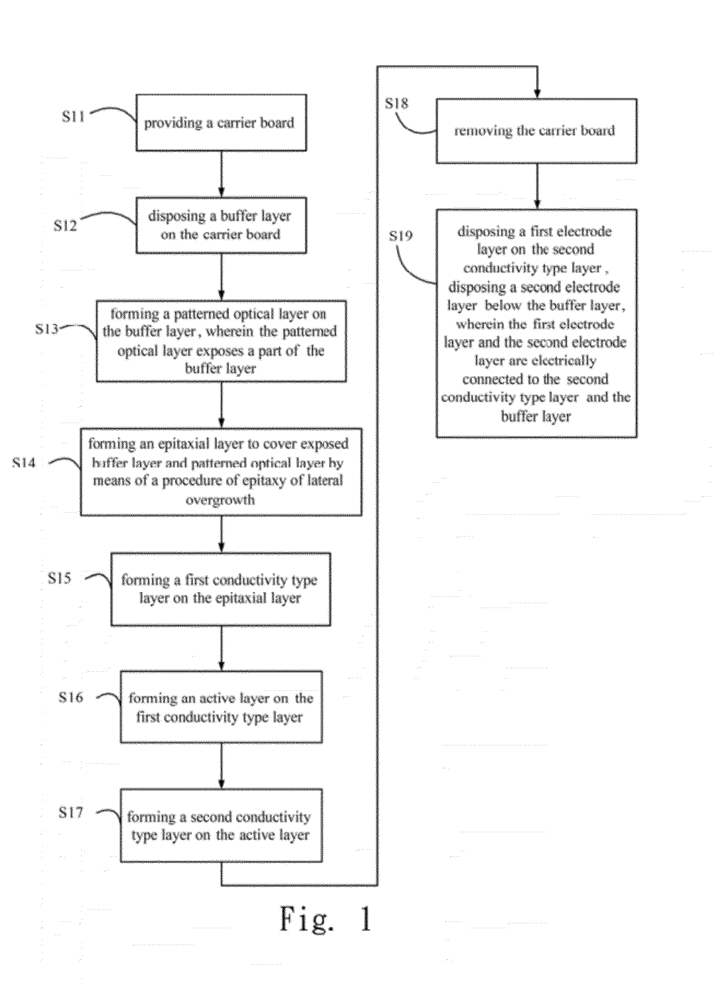

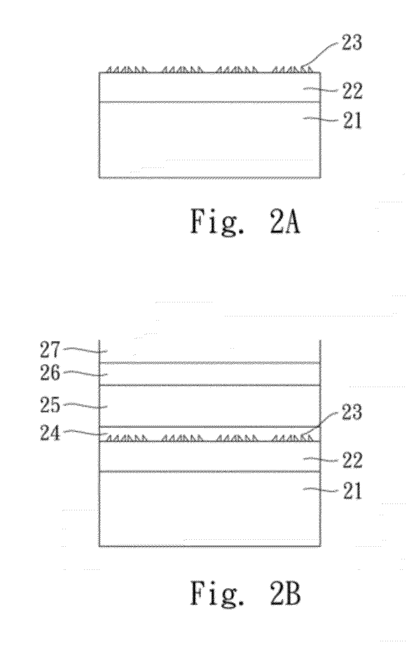

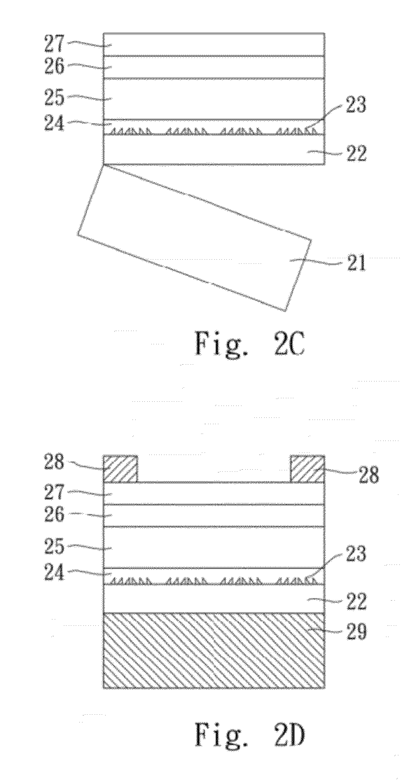

Referring to FIG. 1 and FIG. 2A to FIG. 2D simultaneously, FIG. 1 is a flow diagram illustrating a manufacturing process (Step S11 through Step S19) of a collimating light emitting device according to an embodiment of the present invention. FIG. 2A to FIG. 2D are schematic cross-sectional views illustrating the manufacturing process flow of the collimating light emitting device according to the embodiment of the present invention. FIG. 2A is referred as Step S11 to Step S13 in FIG. 1. At Step S11, a carrier board 21 is provided, and the carrier board 21 may be made of sapphire, SiC, Si, GaAs, LiAlO₂, LiGaO₂ or organic materials. A buffer layer 22 is disposed on the carrier board 21 at Step S12, wherein the buffer layer may comprise undoped III-V semiconductor material. In one embodiment of the present invention, the buffer layer 22 may comprise GaN. A patterned optical layer 23 is formed on the buffer layer 22 at Step S13, wherein the patterned optical layer 23 exposes a part of the buffer layer 22. Regarding to Step S13, the patterned optical layer 23 material disposed on the buffer layer 22 may be achieved by using a sputtering process, an evaporation process, a chemical vapor deposition, a chemical liquid deposition, a chemical vapor epitaxy or a chemical liquid epitaxy, and the optical layer 23 is then patterned by means of photolithography or laser etching. The patterned optical layer 23 may be made of TiO₂, Ta₂O₅, Nb₂O₅, CeO₂, ZnS, ZnO, SiO₂ or MgF₂.

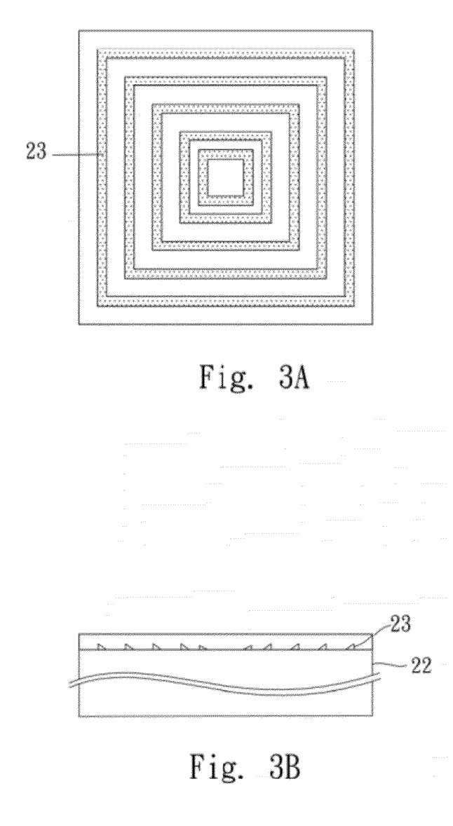

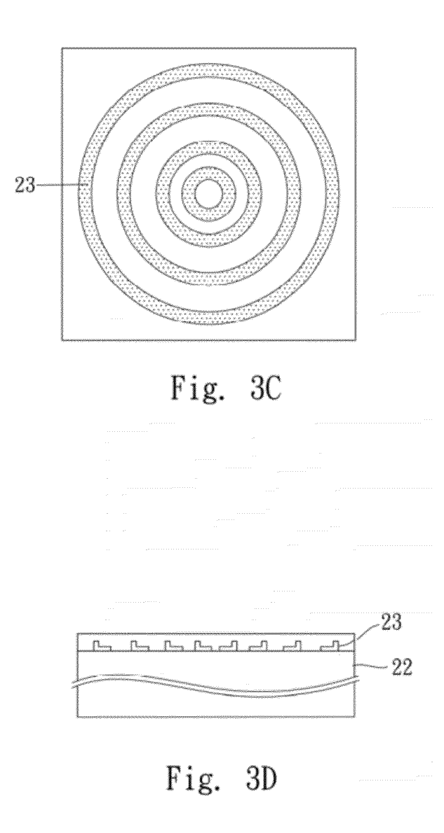

In one embodiment of the present invention as shown in FIG. 2A to FIG. 2D, the patterned optical layer 23 may be, but not limited to be, configured in a plurality of triangle units, the shape of units in the patterned optical layer 23 may include triangle, rectangle, square, arc, trapezoid or combinations thereof. Please referring to FIG. 3A to FIG. 3D simultaneously, FIG. 3A and FIG. 3B are respectively a cross-sectional view and a plan view illustrating the patterned optical layer 23 of the collimating light emitting device according to one embodiment of the present invention; FIG. 3C and FIG. 3D are respectively a cross-sectional view and a plan view illustrating the patterned optical layer 23 of the collimating light emitting device according to another embodiment of the present invention. As shown in FIG. 3A and FIG. 3B, the patterned optical layer 23 comprises a plurality of triangle units configured in a plurality of concentric squares. In the embodiment shown in FIG. 3C and FIG. 3D, the patterned optical layer 23 comprises a plurality of rectangle units configured in a plurality of concentric circles. The patterned optical layer 23 comprises a Fresnel optical structure capable of changing the angle of light reaching to the patterned optical layer 23, so as to provide collimating light. The patterned optical layer 23 may comprise a reflective Fresnel optical layer or a transmissive Fresnel optical layer. In the embodiment shown in FIG. 2A, the patterned optical layer 23 may be a reflective Fresnel optical layer.

Referring to FIG. 2B, FIG. 2B is referred to Step S14 to Step S17 in FIG. 1. At Step S14, an epitaxial layer 24 is formed and covers the exposed buffer layer 22 and patterned optical layer 23 by an epitaxy of lateral overgrowth (ELOG) procedure. The procedures for ELOG may comprise a procedure of molecular beam epitaxy (MBE), metalorganic chemical vapor deposition (MOCVD) or liquid phase deposition. It is noted that the buffer layer 22 is configured for improving the quality of the epitaxial layer 24, the buffer layer 22 may be made of the same material as that of the carrier board 21 (i.e. disposing the buffer layer 22 is not necessary) when the lattice constant of the carrier board 21 matches up with that of the epitaxial layer 24. At Step S15, a first conductivity type layer 25 is formed on the epitaxial layer 24. At Step S16, an active layer 26 is formed on the first conductivity type layer 25. At Step S17, a second conductivity type layer 27 is formed on the active layer 26. The first conductivity type layer 25 may comprise an n-type III-V semiconductor material, such as n-GaN; and the second conductivity type layer 27 comprises a p-type III-V semiconductor material, such as p-GaN. It is understood that material of the first conductivity type layer 25 and the second conductivity type layer 27 may be exchangeable (i.e. the first conductivity type layer 25 may comprise a p-type III-V semiconductor material, and the second conductivity type layer 27 may comprise an n-type III-V semiconductor material). The active layer 26 may comprise a single quantum-well structure or a multiple quantum-well structure and the material and composition thereof may be chosen based on the wave length of light generated from the quantum-well. The manufacturing procedures of the first conductivity type layer 25, the active layer 26 and the second conductivity type layer 27 are similar to those of producing conventional light emitting diodes; thus, detail descriptions are omitted herein.

Continuing the above description, At Step S18, the carrier board 21 is removed, as shown in FIG. 2C, and process of removing the carrier board 21 can be, but not limited by, means of laser peeling. At Step S19, a first electrode layer 28 is disposed on the second conductivity type layer 27 and disposing a second electrode layer 29 below the buffer layer 22, as shown in FIG. 2D. The first electrode layer 28 and the second electrode layer 29 are electrically connected to the second conductivity type layer 27 and the buffer layer 22 respectively. The collimating light emitting device is completed according to the aforementioned steps.

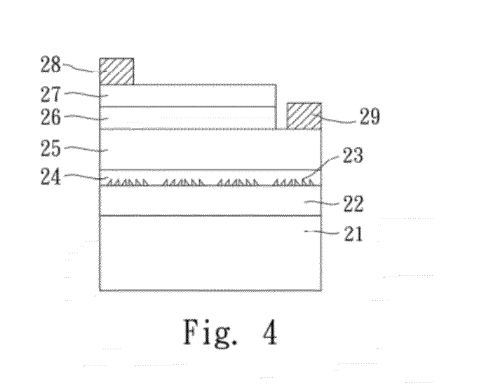

It is noted that the collimating light emitting device shown in FIG. 2D is a vertically conducting light emitting device, wherein the second electrode layer 29 is disposed below the buffer layer 22 and is configured as an external electrode. It could be understood that the second electrode layer 29 may be disposed on the first conductivity type layer 25. Please referring to FIG. 4, FIG. 4 is a schematic diagram illustrating the collimating light emitting device according to another embodiment of the present invention. The first electrode layer 28 and the second electrode layer 29 are disposed on the second conductivity type layer 27 and the first conductivity type layer 25 respectively, and then a parallel conducting light emitting device is formed. The manufacturing process of the parallel conducting light emitting is based on the structure shown in FIG. 2B, a part of the first conductivity type layer 25 is exposed by means of etching process without removing the carrier board 21, followed by disposing the first electrode layer 28 and the second electrode layer 29.

It is noted that the configuration of the first electrode layer 28 and the second electrode layer 29 is dependent on the configuration of the patterned optical layer 23. The manufacturing method of the collimating light emitting device of the present invention is not limited by the order of the process flow shown in FIG. 1; this means that the order of the process flow may be rearranged according to process requirement or the configuration of the patterned optical layer 23, the first electrode layer 28 and the second electrode layer 29. For example, the patterned optical layer 23 of the embodiment of the present invention may comprise a reflective Fresnel optical layer, where the light generated from the active layer reaches at the 26 the patterned optical layer 23, the light is collimated upward vertically and emitted to external environment, wherein the direction is referenced in FIG. 2D. The second electrode layer 29 may comprise a conducting substrate entirely covering the lower surface of the buffer layer 22, and the first electrode layer 28 may comprise a patterned electrode covering a part of the second conductivity type layer 27, according to the configuration of the first electrode layer 28 and the second electrode layer 29, it is known that the collimating light emitting device of the embodiment of the present invention is a vertically conducting structure, and the patterned optical layer 23 (reflective Fresnel optical layer) is configured for collimating light and being able to covert divergent light generated by the active layer 26 into vertical light.

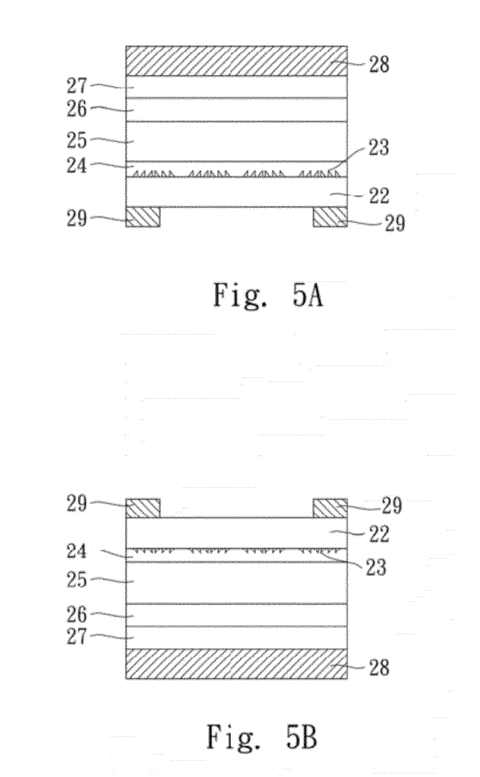

Referring to FIG. 5A and FIG. 5B, FIG. 5A is a schematic diagram illustrating a collimating light emitting device according to another embodiment of the present invention; FIG. 5B is a schematic diagram rotating the schematic diagram in FIG. 5A for 180 degrees clockwise for reference convenience, wherein the patterned optical layer 23 may comprise a transmissive Fresnel optical layer. The first electrode layer comprises a conducting substrate entirely covering the second conductivity type layer 27, and the second electrode layer 29 comprises a patterned second electrode covering a part of the lower surface of the buffer layer 22. The patterned optical layer 23 (transmissive Fresnel optical layer) is configured for collimating light and able to covert divergent light generated by the active layer 26 into vertical light. The light generated from the active layer 26 reaches at the patterned optical layer 23, the light is collimated downward vertically and emitted to external environment, wherein the direction is referenced in FIG. 5A.

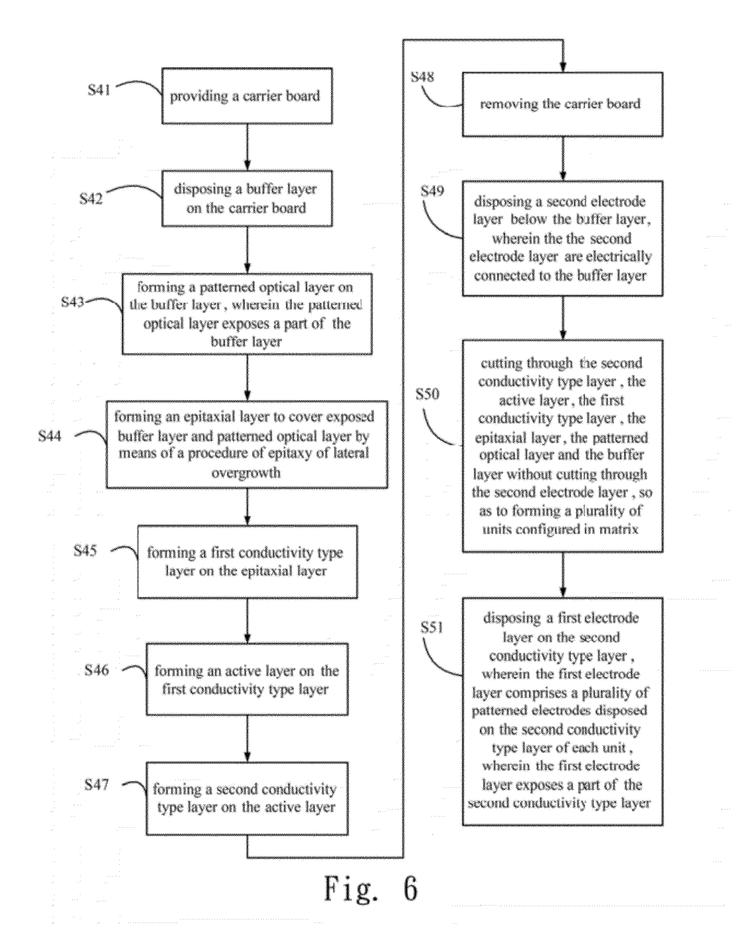

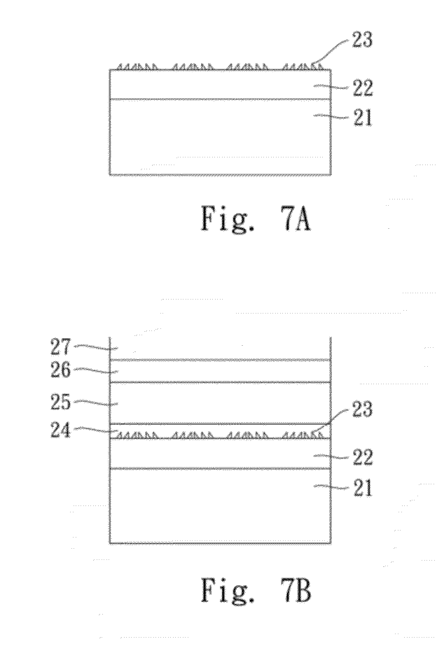

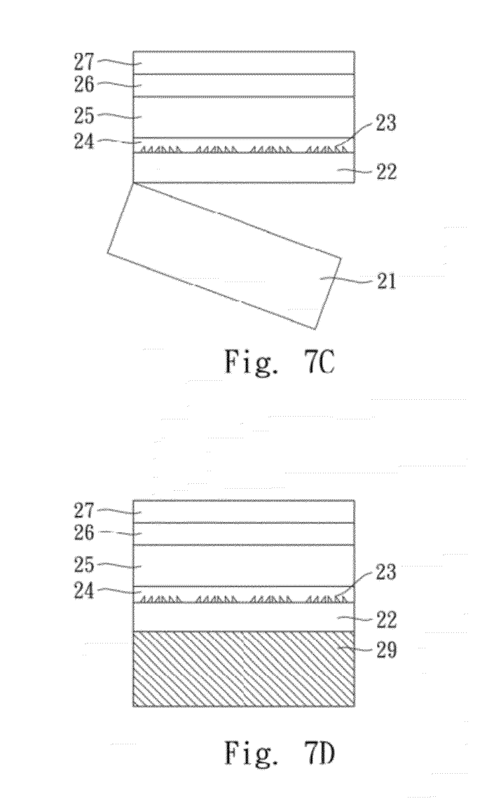

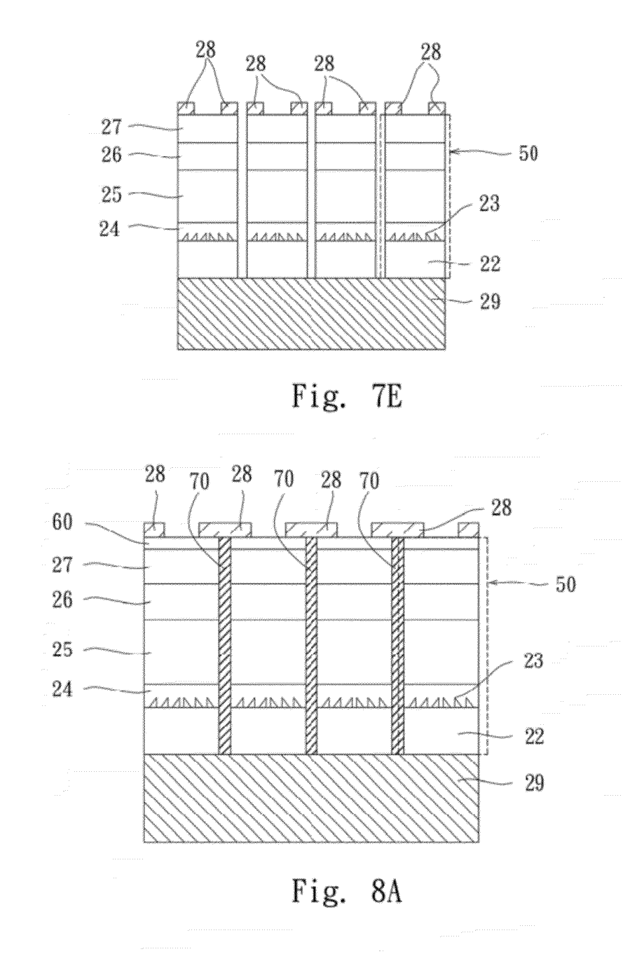

Referring to FIG. 6 and FIG. 7A to FIG. 7E simultaneously, FIG. 6 is a flow diagram illustrating manufacturing process flow (Step S41 through Step S51) of a collimating light emitting device configured in array according to an embodiment of the present invention. FIG. 7A to FIG. 7E are schematic cross-sectional views illustrating the manufacturing process flow of the collimating light emitting device configured in array according to the embodiment of the present invention. Steps S41 to S48 and corresponding schematic cross-sectional view FIG. 7A to FIG. 7C are the same as Steps S11 to S18 in FIG. 1 and corresponding schematic cross-sectional view, therefore, detail descriptions are omitted herein. It is noted that the patterned optical layer 23 in this embodiment may be a reflective Fresnel optical layer. FIG. 7D corresponds to Step S49 in FIG. 6, disposing a second electrode layer 29 below the buffer layer 22 after removing the carrier board 21 (Step S48). The second electrode layer 29 is electrically connected to the buffer layer 22, wherein the second electrode layer 29 may comprise a conducting substrate entirely covering the lower surface of the buffer layer 22.

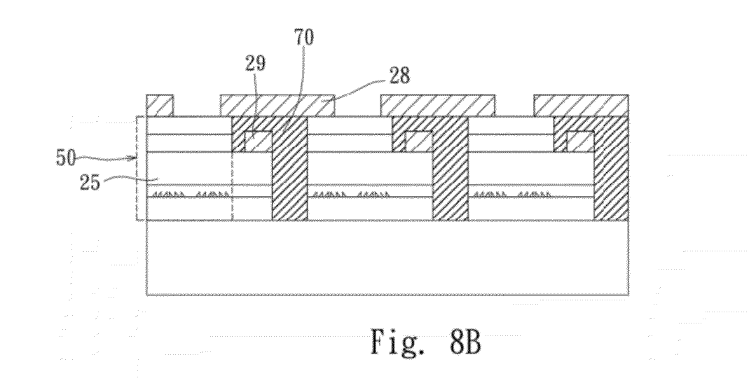

Continuing the above description, FIG. 7E corresponds to Step S50 to Step S51 in FIG. 6. At Step S50, the second conductivity type layer 27, the active layer 26, the first conductivity type layer 25, the epitaxial layer 24, the patterned optical layer 23 and the buffer layer 22 are cut through, wherein the second electrode layer 29 is not cut through so as to form a plurality of units 50 configured in array. At Step S51, a first electrode layer 28 is disposed, wherein the first electrode layer 28 comprises a plurality of patterned electrodes disposed on the second conductivity type layer 27 of each unit 50, wherein the first electrode layer 28 exposes a part of the second conductivity type layer 27. The patterned optical layer 23 in this embodiment may comprise a reflective Fresnel optical layer, and the patterned optical layer 23 configured in array is able to redirect a divergent light to a focusing light beam in uniform direction without utilizing external lenses thereby decreasing the size. Besides, the structure shown in FIG. 7E is a light emitting diode configured in array may be utilized as a micro projection device having advantages of low power consumption and long lifetime. FIG. 8A is a schematic diagram illustrating a collimating light emitting device according to another embodiment of the present invention, the embodiment shown in FIG. 8A further comprises a transparent conducting layer 60 disposing between the first electrode layer 28 and the second conductivity type layer 27 for spreading the current evenly to enhance luminescence efficiency. It is understood that the transparent conductive layer is selected from a group consisting of IZO, ITO, SnO₂, TiO₂, Al₂O₃, InO and ZnO. Preferably, another embodiment of the invention further comprises a plurality of insulating layers 70 disposed between the units 50. The insulating layers 70 comprise insulating materials. The collimating light emitting devices shown in FIG. 7E and FIG. 8A are vertically conducting light emitting device configured in array. It could be understood that the collimating light emitting devices may also comprise a parallel conducting light emitting device configured in array. Referring to FIG. 8B, FIG. 8B is a schematic diagram illustrating a collimating light emitting device according to another embodiment of the present invention, wherein a plurality of second electrode layers 29 are respectively disposed on the first conductivity type layer 25 of each unit 50, and a plurality of insulating layers 70 are disposed between units 50, and a part of the first electrode layer 28 covers the insulating layer 70.

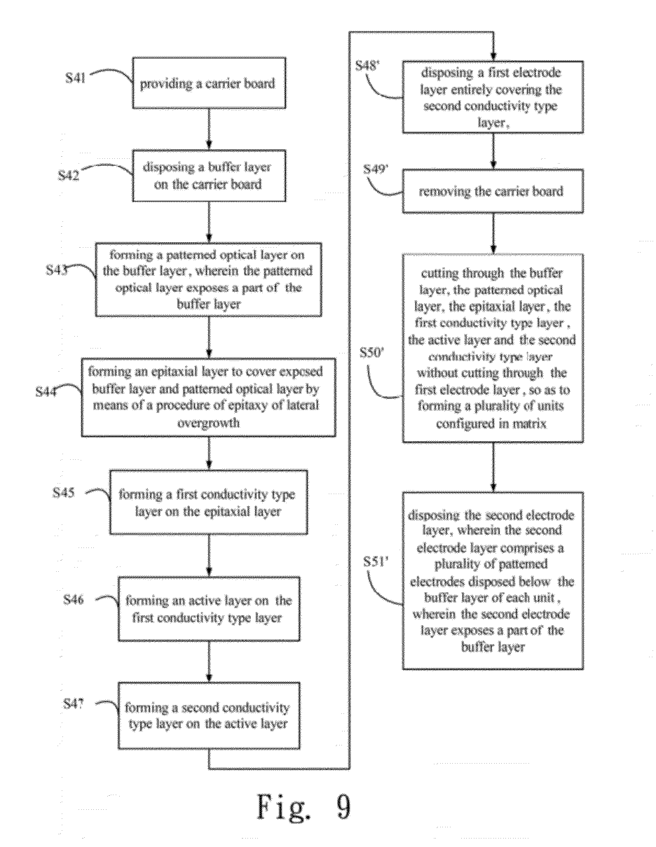

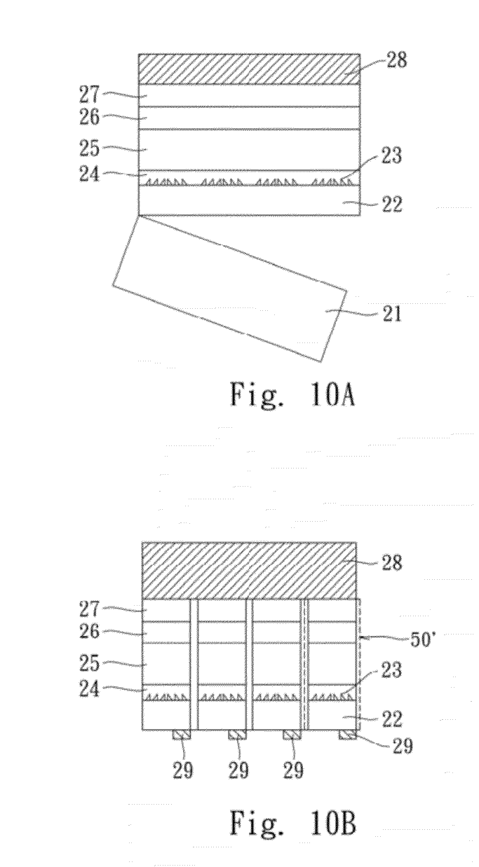

It is noted that the manufacturing method of the collimating light emitting device of the present invention is not limited by the order of the process flow shown in FIG. 6. As the aforementioned descriptions, the configuration of the first electrode layer 28 and the second electrode layer 29 depend on the configuration of the patterned optical layer 23. Configuration of the first electrode layer 28 and the second electrode layer 29 and the order of the process flow are changed, when the patterned optical layer 23 comprises a transmissive Fresnel optical layer. Referring to FIG. 9 and FIG. 10A to 10B simultaneously, FIG. 9 is a manufacturing process flow (Step S41 to Step S47 and Step S48′ to Step S51′) of a collimating light emitting device according to another embodiment of the present invention. FIG. 10A and FIG. 10B are schematic cross-sectional views illustrating the manufacturing process flow of the collimating light emitting device according to the embodiment of the present invention. Steps S41 to 47 in FIG. 9 are the same as Steps S41 to S47 in FIG. 6. FIG. 10A corresponds to Step S48′ to Step S49′ in FIG. 9, at Step S48′, a first electrode layer 28 is disposed, wherein the first electrode layer 28 comprises a conducting substrate entirely covering the second conductivity type layer 27. At Step S49′, the carrier board 21 is removed.

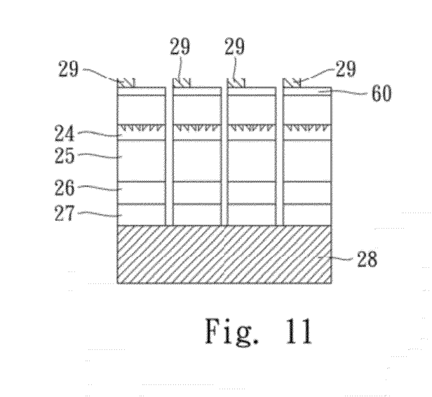

Continuing the above description, FIG. 10B corresponds to Step S50′ to Step S51′ in FIG. 9. Step S50′ is cutting through the buffer layer 22, the patterned optical layer 23, the epitaxial layer 24, the first conductivity type layer 25, the active layer 26 and the second conductivity type layer 27 without cutting through the first electrode layer 28, so as to form a plurality of units 50′ configured in array. At Step S51′, the second electrode layer 29 is deposed, wherein the second electrode layer 29 comprises a plurality of patterned electrodes disposed below the buffer layer 22 of each unit 50′, wherein the second electrode layer 29 exposes a part of the buffer layer 22. The patterned optical layer 23 in this embodiment may comprise a transmissive Fresnel optical layer, and the patterned optical layer 23 configured in array is able to redirect a divergent light to a focusing light beam in uniform direction without utilizing external lenses thereby decreasing the size. Besides, the structure shown in FIG. 10B is a light emitting diode configured in array may be utilized as a micro projection device having advantages of low power consumption and long lifetime. FIG. 11 is a schematic diagram illustrating a collimating light emitting device according to another embodiment of the present invention, the embodiment shown in FIG. 11 further comprises a transparent conducting layer 60 disposing between the second electrode layer 29 and the buffer layer 22 for spreading the current evenly to enhance luminescence efficiency. It is noted that FIG. 11 is a schematic diagram rotating the schematic diagram in FIG. 10B for 180 degrees clockwise for reference convenience.

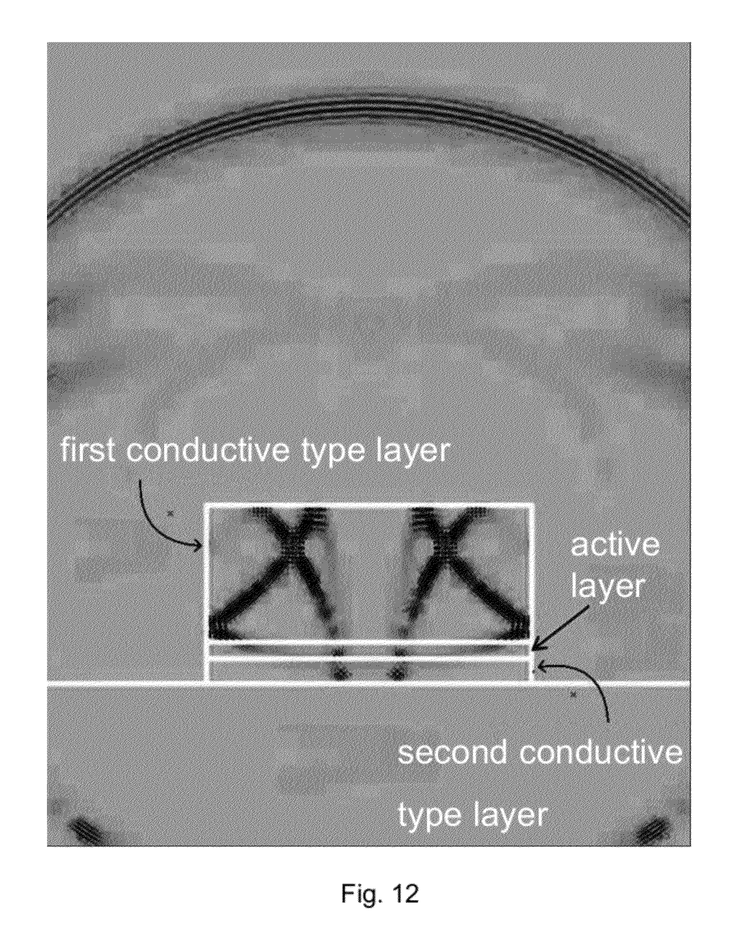

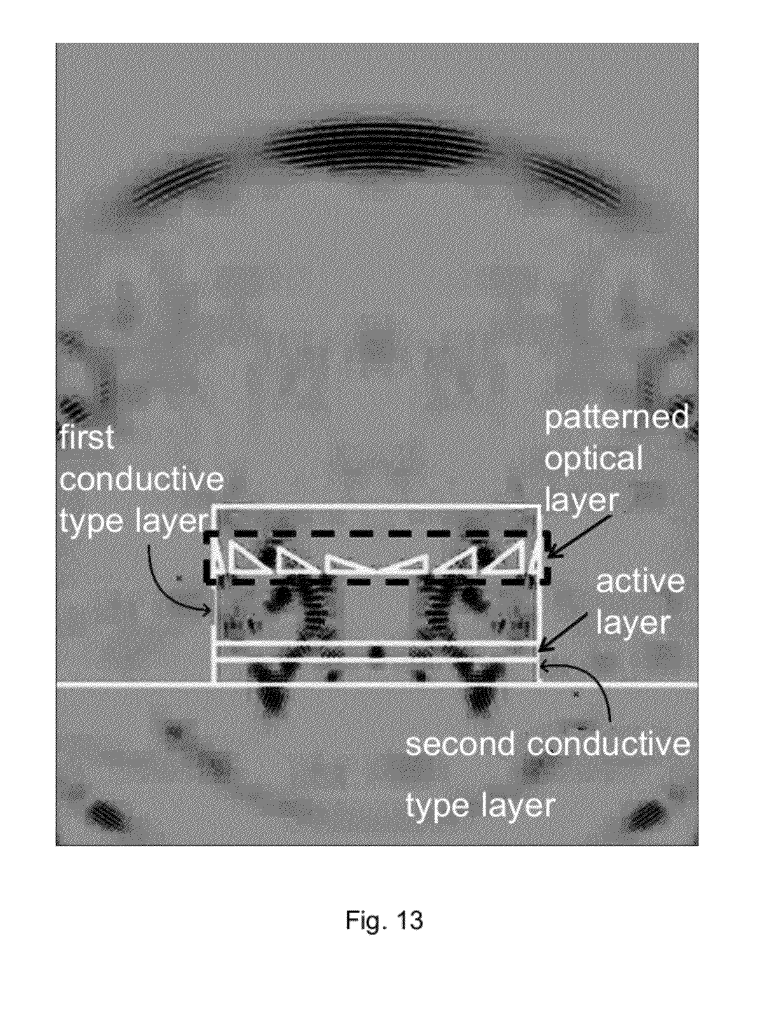

Referring to FIGS. 12 and 13, which are simulation diagrams of light field distribution illustrating the characteristics of the patterned optical layer (Fresnel optical structure), wherein Appendix 1 represents a simulation diagram of light field distribution of a conventional light emitting diode (i.e. no patterned optical layer (Fresnel optical structure) within); Appendix 2 represents a simulation diagram of light field distribution of a light emitting device with patterned optical layer (Fresnel optical structure) inside the device. It is shown that the light field distribution of the light emitting device with patterned optical layer is more concentrated than that of the conventional light emitting diode, therefore, the patterned optical layer (Fresnel optical structure) of the collimating light emitting device of the present invention has the effect of light collimating.

In summary, the collimating light emitting device comprises a patterned optical layer able to redirect divergent light to light beam with uniform direction thereby having good light collimation. The patterned optical layer comprises a reflective or a transmissive Fresnel optical layer. The collimating light emitting device configured in array may be may be utilized as a micro array projection device without utilizing external lenses thereby decreasing the size. The manufacturing methods of the collimating light emitting device are also presented. The dimension of the collimating light emitting device of the present invention may be 1 mil to 50 mil depending on the volume of the projection device, the area or the resolution of the projecting image.

While the invention is susceptible to various modifications and alternative forms, a specific example thereof has been shown in the drawings and is herein described in detail. It is understood, however, that the invention is not to be limited to the particular form disclosed, but to the contrary, the invention is to cover all modifications, equivalents, and alternatives falling within the spirit and scope of the appended claims.

What is claimed is:

1. A manufacturing method of a collimating light emitting device comprising:
providing a carrier board;
disposing a buffer layer on said carrier board;
forming a patterned optical layer on said buffer layer, wherein said patterned optical layer exposes a part of said buffer layer;
forming an epitaxial layer to cover said exposed buffer layer and said patterned optical layer by means of a procedure of epitaxy of lateral overgrowth (ELOG);
forming a first conductivity type layer on said epitaxial layer;
forming an active layer on said first conductivity type layer;
forming a second conductivity type layer on said active layer;
disposing a first electrode layer on said second conductivity type layer; and
disposing a second electrode layer either below said buffer layer or on said first conductivity type layer, wherein a procedure of removing said carrier board is performed before disposing said second electrode layer below said buffer layer.

2. The manufacturing method according to claim 1, wherein said patterned optical layer comprises a reflective Fresnel optical layer.

3. The manufacturing method according to claim 2, wherein said first electrode layer comprises a patterned electrode covering a part of said second conductivity type layer; and said second electrode layer comprises a conducting substrate entirely covering the lower surface of said buffer layer.

4. The manufacturing method according to claim 2, wherein said procedure of removing said carrier board is followed by:
disposing said second electrode layer, wherein said second electrode layer comprises a conducting substrate entirely covering the lower surface of said buffer layer;
cutting through said second conductivity type layer, said active layer, said first conductivity type layer, said epitaxial layer, said patterned optical layer and said buffer layer without cutting through said second electrode layer so as to form a plurality of units configured in array; and
disposing said first electrode layer, wherein said first electrode layer comprises a plurality of patterned electrodes disposed on said second conductivity type layer of each said unit, wherein said first electrode layer exposes a part of said second conductivity type layer.

5. The manufacturing method according to claim 1, wherein said patterned optical layer comprises a transmissive Fresnel optical layer.

6. The manufacturing method according to claim 5, wherein said first electrode layer comprises a conducting substrate entirely covering said second conductivity type layer; and said second electrode layer comprises a patterned electrode covering a part of the lower surface of said buffer layer.

7. The manufacturing method according to claim 5, wherein disposing said first electrode layer is followed by:
removing said carrier board, wherein said first electrode layer comprises a conducting substrate entirely covering said second conductivity type layer;
cutting through said buffer layer, said patterned optical layer, said epitaxial layer, said first conductivity type layer, said active layer and said second conductivity type layer without cutting through said first electrode layer, so as to form a plurality of units configured in array; and
disposing said second electrode layer, wherein said second electrode layer comprises a plurality of patterned electrodes disposed below said buffer layer of each said unit, wherein said second electrode layer exposes a part of said buffer layer.

8. The manufacturing method according to claim 1, further comprising forming a transparent conducting layer between said first electrode layer and said second conductivity type layer.

9. The manufacturing method according to claim 1, further comprising forming a transparent conducting layer between said second electrode layer and said buffer layer.

10. The manufacturing method according to claim 1, wherein said buffer layer comprises undoped III-V semiconductor material.

11. The manufacturing method according to claim 1, wherein said first conductivity type layer comprises an n-type III-V semiconductor material; and said second conductivity type layer comprises a p-type III-V semiconductor material.

12. The manufacturing method according to claim 1, wherein said first conductivity type layer comprises a p-type III-V semiconductor material; and said second conductivity type layer comprises a n-type III-V semiconductor material.

13. A collimating light emitting device comprising:
a buffer layer;
a patterned optical layer, disposed on said buffer layer, wherein said patterned optical layer exposes a part of said buffer layer;
an epitaxial layer, covering exposed said buffer layer and said patterned optical layer;
a first conductivity type layer, disposed on said epitaxial layer;
an active layer, disposed on said first conductivity type layer;
a second conductivity type layer, disposed on said active layer;
a first electrode layer, disposed on said second conductivity type layer; and
a second electrode layer, disposed either below said buffer layer or on said first conductivity type layer.

14. The collimating light emitting device according to claim 13, wherein said patterned optical layer comprises a reflective Fresnel optical layer.

15. The collimating light emitting device according to claim 14, wherein said first electrode layer comprises a patterned first electrode covering a part of said second conductivity type layer; and said second electrode layer comprises a conducting substrate entirely covering the lower surface of said buffer layer.

16. The collimating light emitting device according to claim 14, further comprising:
a trench, penetrating said second conductivity type layer, said active layer, said first conductivity type layer, said epitaxial layer, said patterned optical layer and said buffer layer without penetrating said second electrode layer, wherein said trench defines a plurality of units configured in array, wherein said first electrode layer comprises a plurality of patterned first electrodes disposed on said second conductivity type layer of each said unit, wherein said first electrode layer exposes a part of said second conductivity type layer, and said second electrode layer comprises a conducting substrate entirely covering the lower surface of said buffer layer.

17. The collimating light emitting device according to claim 13, wherein said patterned optical layer comprises a transmissive Fresnel optical layer.

18. The collimating light emitting device according to claim 17, wherein said first electrode layer comprises a conducting substrate entirely covering said second conductivity type layer; and said second electrode layer comprises a patterned second electrode covering a part of the lower surface of said buffer layer.

19. The collimating light emitting device according to claim 17, further comprising:
a trench, penetrating said buffer layer, said patterned optical layer, said epitaxial layer, said first conductivity type layer, said active layer and said second conductivity type layer and without penetrating said first electrode layer, wherein said trench defines a plurality of units configured in array, wherein said first electrode layer comprises a conducting substrate entirely covering said second conductivity type layer, and said second electrode layer comprises a plurality of patterned second electrodes disposed on said buffer layer of each said unit, wherein said second electrode layer exposes a part of said buffer layer.

20. The collimating light emitting device according to claim 13, further comprising a transparent conducting layer disposed between said first electrode layer and said second conductivity type layer.

21. The collimating light emitting device according to claim 13, further comprising further comprising a transparent conducting layer disposed between said second electrode layer and said buffer layer.

22. The collimating light emitting device according to claim 13, wherein said buffer layer comprises undoped III-V semiconductor material.

23. The collimating light emitting device according to claim 13, wherein said first conductivity type layer comprises a n-type III-V semiconductor material; and said second conductivity type layer comprises a p-type III-V semiconductor material.

24. The collimating light emitting device according to claim 13, wherein said first conductivity type layer comprises a p-type III-V semiconductor material; and said second conductivity type layer comprises a n-type III-V semiconductor material.
